(19) United States
(12) Patent Application Publication
(10) Pub. No.: US 2014/0021592 A1
(43) Pub. Date: Jan. 23, 2014

(54) LED LEAD FRAME STRUCTURE AND METHOD OF MANUFACTURING LED LEAD FRAME

(71) Applicant: TECHWIN OPTO-ELECTRONICS CO., LTD., New Taipei City (TW)

(72) Inventor: Chih-Lin CHI, New Taipei City (TW)

(73) Assignee: TECHWIN OPTO-ELECTRONICS CO., LTD., NEW TAIPEI CITY (TW)

(21) Appl. No.: 13/844,144

(22) Filed: Mar. 15, 2013

(30) Foreign Application Priority Data
Jul. 19, 2012 (TW) 101126033

(51) Int. Cl. H01L 33/62

(52) U.S. Cl. CPC H01L 33/62
USPC 257/666; 438/666

(57) ABSTRACT

A LED lead frame structure and a method of manufacturing LED lead frames are disclosed, in which the LED lead frame structure includes a metal base and insulating casings. The metal base has a plurality of lead areas, and two holes are formed on two opposing sides of each lead area. The insulating casings are formed on the lead areas respectively.

### CROSS-REFERENCE TO RELATED APPLICATIONS

This application claims priority to Taiwan Application Serial Number 101126033, filed Jul. 19, 2012, which is herein incorporated by reference.

### BACKGROUND OF THE INVENTION

1. Field of the Invention

The present disclosure relates to lead frame structures and methods for manufacturing the same, and more particularly, lead frame structures of light-emitting diodes (LEDs) and methods for manufacturing LED lead frames.

2. Description of the Related Art

Recently, with the progression of the industry and commerce and the advancements in human society, the products on the market are aimed to be convenient, accurate, and economical. Therefore, the products that are developed are better than the old products and make contributions to the society.

Light-emitting diodes (LEDs) are semiconductor devices capable of emitting light. Appearing as practical electronic components in 1962, early LEDs emitted low-intensity red light, but modern versions are available across the visible, ultraviolet, and infrared wavelengths, with very high brightness. With the development of white LEDs, the application of LEDs goes from indicators and display boards to illumination.

When a light-emitting diode is forward-biased, electrons are able to recombine with electron holes within the device, releasing energy in the form of photons. This effect is called electroluminescence and the color of the light is determined by species of semiconductor materials and artificially introduced dopants. LEDs present many advantages over conventional light sources including lower energy consumption, longer lifetime, improved physical robustness, faster response, and high reliability.

However, as illustrated in FIG. 1, in conventional methods for the manufacturing of LED lead frames, the insulating casing 110 tends to crack (indicated by oblique lines) when the product undergoes material release. Therefore, the yield rate is decreased, and the production capacity is hampered.

In view of the foregoing, there exist problems and disadvantages in the current manufacturing methods that await further improvement. However, those skilled in the art sought vainly for a solution. In order to solve or circumvent above problems and disadvantages, there is an urgent need in the related field to avoid the crack of the insulating casing.

### SUMMARY

The following presents a simplified summary of the disclosure in order to provide a basic understanding to the reader. This summary is not an extensive overview of the disclosure and it does not identify key/critical elements of the present invention or delineate the scope of the present invention. Its sole purpose is to present some concepts disclosed herein in a simplified form as a prelude to the more detailed description that is presented later.

In view of the foregoing, one aspect of the present disclosure is directed to a method for manufacturing an LED lead frame, and an LED lead frame structure, in which the crack of the insulating casing is substantially avoided.

According to one embodiment of the present disclosure, the method for manufacturing an LED lead frame includes the steps of: providing a metal substrate; forming multiple lead areas on the metal substrate, and forming two slug holes on two opposite sides of each lead area; forming an insulating casing on each lead area; when stamping each lead area, pressing from the two opposite sides of each lead area toward the two slug holes, such that each lead area is disengaged from the metal substrate, whereby obtaining the multiple LED lead frame.

In certain manufacturing methods, the insulating casing is made of a thermoplastic material or a thermoset material.

In some manufacturing methods, the insulating casing is formed on each lead area by injection molding.

In other manufacturing methods, two slug holes are formed on the first pair of two opposite sides of each lead area, and two openings are formed on the second pair of two opposite sides of each lead area, wherein in each lead area, the first pair of two opposite sides is longer than the second pair of the two opposite sides.

In some manufacturing methods, each of the slug holes has an elongated bar shape, in which the length of the elongated bar is greater than or equal to the length of the first pair of two opposite sides of each lead area.

According to another embodiment of the present disclosure, an LED lead frame structure comprises a metal substrate and multiple insulating casings. The metal substrate has multiple lead areas, wherein two slug holes are disposed on two opposite sides of each lead area. The multiple insulating casings are disposed on each of the multiple lead areas.

In certain LED lead frame structures, the insulating casing is made of a thermoplastic material or a thermoset material.

In some LED lead frame structures, the insulating casing is disposed on each lead area by injection molding.

In other LED lead frame structures, two slug holes are disposed on the first pair of two opposite sides of each lead area, and two openings are formed on the second pair of two opposite sides of each lead area, wherein in each lead area, the first pair of two opposite sides is longer than the second pair of the two opposite sides.

In some LED lead frame structures, each of the slug holes has an elongated bar shape, in which the length of the elongated bar is greater than or equal to the length of the first pair of two opposite sides of each lead area.

In view of the foregoing, the technical solution provided by the present disclosure has significant benefits and advantages over the conventional technology. Substantial technical advancement is achieved by the above-mentioned technical solution, and a variety of applications in the industry are attained. Specifically, the present technical solution has, at least, the following advantages:

1. During the stamping of the lead areas, the material is pressed from the two opposite sides of the lead areas toward the slug holes by the side, which prevents the insulating casing from cracking, and facilitate the natural disengagement of each lead area from the metal substrate, thereby obtaining multiple products (i.e., the LED lead frame); and

2. Improves the yield rate and production capacity.

Many of the attendant features and advantages of the present disclosure will becomes better understood with reference to the following detailed description considered in connection with the accompanying drawing.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

The present description will be better understood from the following detailed description read in light of the accompanying drawing, wherein:

FIG. 1 is a schematic drawing illustrating the crack of the insulating casing of the of a conventional LED lead frame;

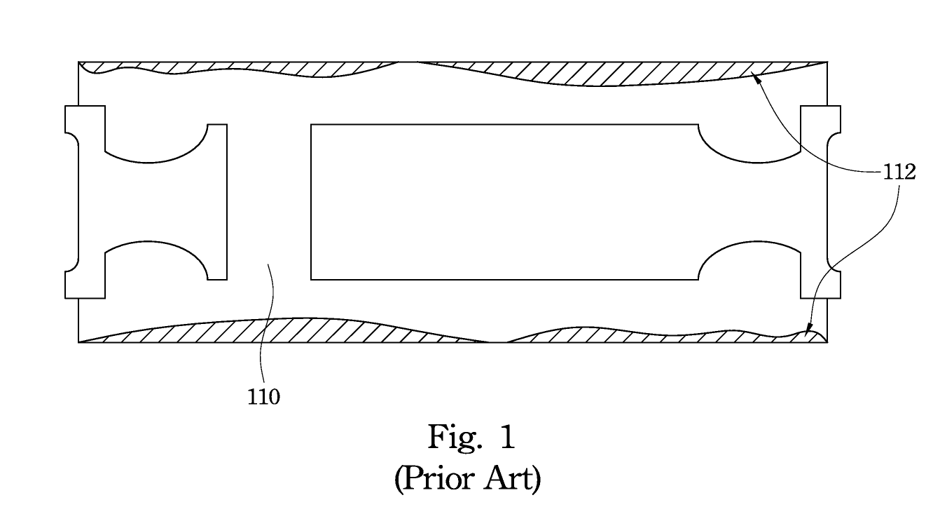

FIG. 2 is a flow chart illustrating the method for manufacturing LED lead frames according to one embodiment of the present disclosure;

FIG. 3 is a schematic plane view of an LED lead frame structure according to one embodiment of the present disclosure, before the material release; and

FIG. 4 is a schematic plane view of an LED lead frame structure according to another embodiment of the present disclosure, after the material release.

### DETAILED DESCRIPTION

In the following detailed description, for purposes of explanation, numerous specific details are set forth in order to attain a thorough understanding of the disclosed embodiments. It will be apparent, however, that one or more embodiments may be practiced without these specific details. In other instances, well-known structures and devices are schematically shown in order to simplify the drawing.

As used in the description herein and throughout the claims that follow, the meaning of “a”, “an”, and “the” includes reference to the plural unless the context clearly dictates otherwise.

Also, as used in the description herein and throughout the claims that follow, the term “about” modifying any quantity refers to variation in the numerical quantity that would not affect the nature of the quantity. Unless specified otherwise, in the present embodiments, the term “about” means within 20% of the reported numerical value, preferably within 10% of the reported numerical value, and more preferably within 5% of the reported numerical value.

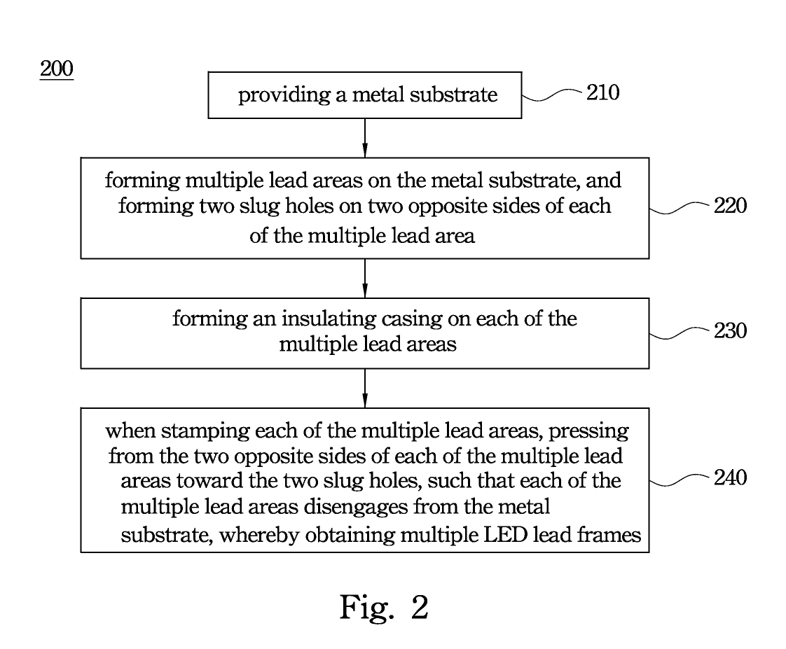

In one technical aspect, the present disclosure is directed to a method for manufacturing LED lead frames. This method may be used is industrial production or widely in other relevant technical fields. It should be noted that the present manufacturing method could prevent the insulating casing from cracking. The specific embodiments exemplifying the present manufacturing method are described below in conjunction with FIG. 2 to FIG. 4.

FIG. 2 is a flow chart illustrating a manufacturing method 200 according to one embodiment of the present disclosure for the manufacture of LED lead frames. As illustrated in FIG. 2, the manufacturing method 200 comprises steps 210 to 240. However, as could be appreciated, the sequential orders of the steps recited in the embodiments could be adjusted as required, and all or some of the steps may occur concurrently.

First, in step 210, a metal substrate is provided; in step 220, multiple lead areas are formed on the metal substrate, and two slug holes are formed on two opposite sides of each lead area; in step 230, an insulating casing is formed on each lead area; in step 240, when stamping each lead area, pressing from the two opposite sides of each lead area toward the two slug holes to prevent the insulating casing from cracking, and allow each lead area to disengage from the metal substrate, whereby obtaining multiple products (i.e., the LED lead frames).

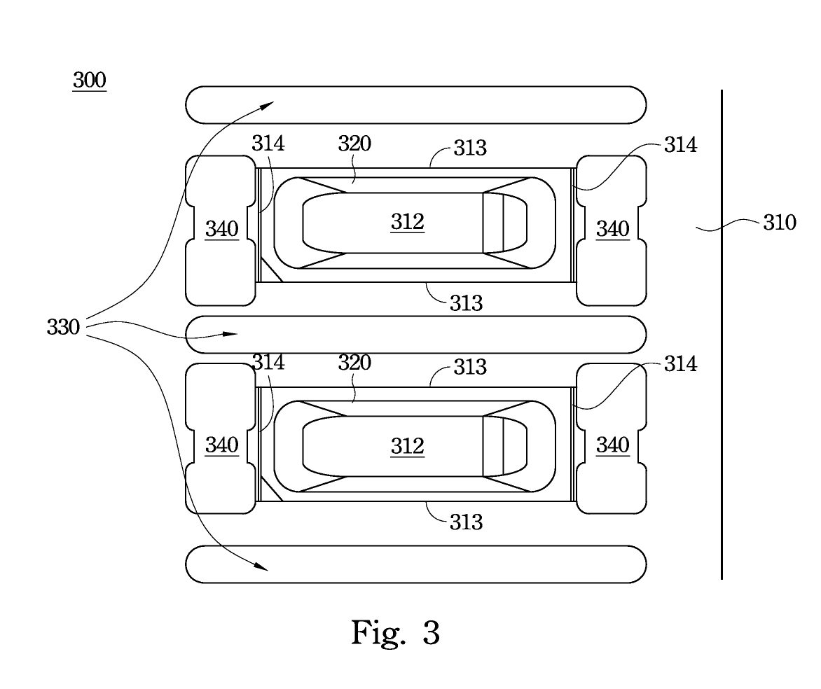

To further elaborate the above-mentioned steps 210 to 230, reference is now directed to FIG. 3, which is a schematic plane view that depicts an LED lead frame structure 300, before the material release, according to one embodiment of the present disclosure. As illustrated in FIG. 3, the LED lead frame structure 300 comprises a metal substrate 310 and multiple insulating casings 320. From the structural perspective, the metal substrate 310 has multiple lead areas 312, in which each lead area 312 has two slug holes 330 disposed on two opposite sides thereof. The multiple insulating casing 320 is disposed on these lead areas 312.

Specifically, two slug holes 330 are disposed by the side of a first pair of two opposite sites 313 of each lead area 312, whereas two openings 340 are disposed by the second pair of two opposite sites 314, wherein the first pair of two opposite sites 313 is longer than the second pair of two opposite sites 314.

In FIG. 3, each slug hole 330 has an elongated bar shape, in which the length of the elongated bar-like slug hole is greater than or equal to the length of the first pair of two opposite sites 313. In this way, the elongated bar-like slug hole have sufficient space to deform during the material release, and therefore, the cracking of the insulating casing 320 is prevented.

In practice, the insulating casing 320 is disposed on each lead area 312 by injection molding. In one embodiment, the insulating casing 320 is made of a thermoplastic material, in which the thermoplastic material could be repeatedly heated, melted, and solidified into desired shape. For example, the thermoplastic material may be polyethylene (PE), polypropylene (PP), polystyrene (PS), acrylonitrile/butadiene/styrene (ABS) resin, polyvinylchloride (PVC), acrylic resin, polycarbonate (PC), fluroresin, or other suitable materials, or the derivatives or combination thereof.

Alternatively, in other embodiments, the insulating casing 320 is made of a thermoset material, thermoset material in which the thermoset material could be heated to a specific temperature and solidified, and subsequent heating would not alter the phase of the material. For example, the thermoset material is phenol-formaldehyde resin, urea resin, epoxy resin, silicone resin, melamine, or other suitable materials, or the derivatives or combination thereof.

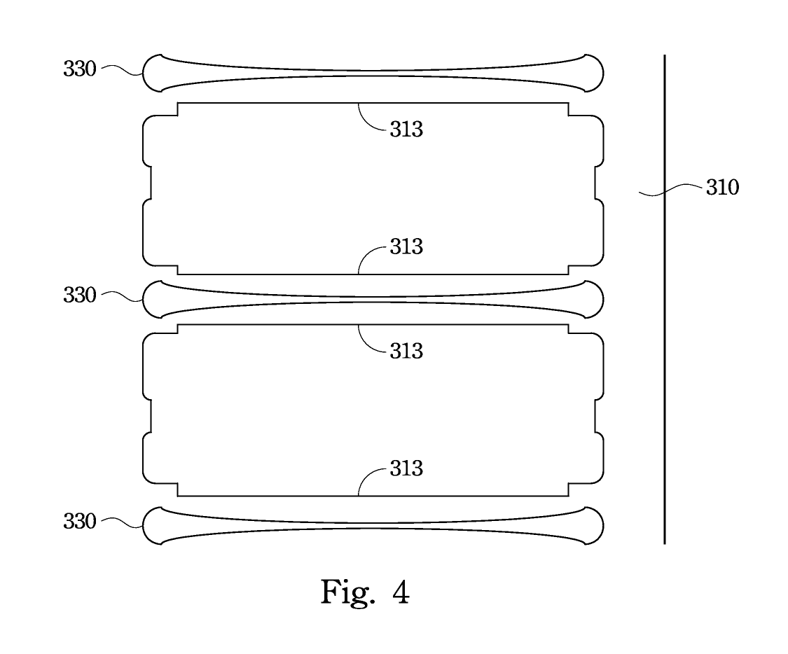

On the other hand, to further elaborate the above-mentioned step 240, reference is now directed to FIG. 4, which is a schematic plane view that depicts an LED lead frame structure 300, after the material release, according to one embodiment of the present disclosure. As illustrated in FIG. 4, when stamping the lead areas (as illustrated in FIG. 3), the material is pressed from the two opposite sides 313 of the lead areas toward the two slug holes 330. In this instance, the slug holes 330 are deformed under the pressure, thereby preventing the insulating casing 320 from cracking. Therefore, the yield rate and production capacity are improved. Further, the lead areas, in conjunction with the crack-free insulating casings, after being disengaged from the metal substrate 310, could be used as multiple LED lead frames. Such LED lead frames are suitable to bear LED and provide electrical communication. This technology is well-known by persons having ordinary skills in the art, and is not part of the protection scope of the present disclosure, and hence detailed description regarding that aspect is omitted herein.

It will be understood that the above description of embodiments is given by way of example only and that various modifications may be made by those with ordinary skill in the art. The above specification, examples and data provide a complete description of the structure and use of exemplary embodiments of the invention. Although various embodiments of the invention have been described above with a certain degree of particularity, or with reference to one or more individual embodiments, those with ordinary skill in the art could make numerous alterations to the disclosed embodiments without departing from the spirit or scope of this invention.

What is claimed is:

1. A method for manufacturing a light-emitting diode (LED) lead frame, comprising the steps of:
providing a metal substrate;
forming multiple lead areas on the metal substrate, and forming two slug holes on two opposite sides of each of the multiple lead area;
forming an insulating casing on each of the multiple lead areas; and
when stamping each of the multiple lead areas, pressing from the two opposite sides of each of the multiple lead areas toward the two slug holes, such that each of the multiple lead areas disengages from the metal substrate, whereby obtaining multiple LED lead frames.

2. The method of claim 1, wherein the insulating casing is a thermoplastic material or thermoset material.

3. The method of claim 1, wherein the insulating casing is formed on each of the multiple lead areas by injection molding.

4. The method of claim 1, wherein each of the multiple lead areas has a first pair of two opposite sides wherein the two slug holes are formed by the side of the first pair of two opposite sides; and a second pair of two opposite sides wherein two openings are formed by the side of the second pair of two opposite sides, wherein in each of the multiple lead areas, the first pair of two opposite sides is longer than the second pair of two opposite sides.

5. The method of claim 4, wherein each of the slug holes has an elongated bar shape, and has a length greater than or equal to the length of the first pair of two opposite sides.

6. An LED lead frame structure, comprising:
a metal substrate, comprising multiple lead areas, wherein each of the multiple lead areas has two opposite sides that have two slug holes disposed thereon;
multiple insulating casing, disposed on the multiple lead areas.

7. The LED lead frame structure of claim 6, wherein the insulating casing thermoplastic material or thermoset material.

8. The LED lead frame structure of claim 6, wherein the insulating casing is disposed on each of the multiple lead areas by injection molding.

9. The LED lead frame structure of claim 6, wherein each of the multiple lead areas has a first pair of two opposite sides wherein the two slug holes are disposed by the side of the first pair of two opposite sides; and a second pair of two opposite sides wherein two openings are disposed by the side of the second pair of two opposite sides, wherein in each of the multiple lead areas, the first pair of two opposite sides is longer than the second pair of two opposite sides

10. The LED lead frame structure of claim 9, wherein each of the slug holes has an elongated bar shape, and has a length greater than or equal to the length of the first pair of two opposite sides.
